(19) United States
(12) Patent Application Publication
(10) Pub. No.: US 2025/0275200 A1
(43) Pub. Date: Aug. 28, 2025

(54) SEMICONDUCTOR DEVICE AND MANUFACTURING METHOD THEREOF

(71) Applicant: Fujian Jinhua Integrated Circuit Co., Ltd., Quanzhou City (CN)

(72) Inventors: XUANTONG CHEN, Quanzhou City (CN); Chien-Cheng Tsai, Quanzhou City (CN); Yang Zhou, Quanzhou City (CN); Xianglong He, Quanzhou City (CN)

(73) Assignee: Fujian Jinhua Integrated Circuit Co., Ltd., Quanzhou City (CN)

(21) Appl. No.: 18/616,208

(22) Filed: Mar. 26, 2024

(30) Foreign Application Priority Data
Feb. 26, 2024 (CN) 202410211533.8

(51) Int. Cl. H01L 29/08; H01L 21/768; H01L 29/10; H01L 29/43; H01L 29/66

(52) U.S. Cl. CPC H10D 62/151; H01L 21/76831; H10D 30/027; H10D 62/235; H10D 64/605

(57) ABSTRACT

A semiconductor device and a manufacturing method thereof are in the present invention. The semiconductor device includes a substrate, a source structure, a semiconductor structure, a gate structure, and a doped semiconductor layer. The source structure is disposed on the substrate. The semiconductor structure is disposed above the source structure. The gate structure is disposed above the source structure and surrounds the semiconductor structure. The doped semiconductor layer is disposed between the source structure and the semiconductor structure. Accordingly, the operation performance of the semiconductor device may be improved.

### BACKGROUND OF THE INVENTION

### 1. Field of the Invention

The present invention relates to a semiconductor device and a manufacturing method thereof, and more particularly, to a semiconductor device including a doped semiconductor layer and a manufacturing method thereof.

### 2. Description of the Prior Art

The development of semiconductor integrated circuit technology progresses continuously and circuit designs in products of the new generation become smaller and more complicated than those of the former generation. The amount and the density of the functional devices in each chip region are increased constantly according to the requirements of innovated products, and the size of each device has to become smaller accordingly. The conventional planar metal-oxide-semiconductor (MOS) transistor has difficulty when scaling down in the development of the semiconductor device. Therefore, the stereoscopic transistor technology or the non-planar transistor technology that allows smaller size and higher performance is developed to replace the planar MOS transistor for reducing the dimension of the transistor unit and/or improving the operation performance of the transistor unit.

### SUMMARY OF THE INVENTION

A semiconductor device and a manufacturing method thereof are provided in the present invention. A doped semiconductor layer is disposed between a source structure and a semiconductor structure for improving operation performance of the semiconductor device.

According to an embodiment of the present invention, a semiconductor device is provided. The semiconductor device includes a substrate, a source structure, a semiconductor structure, a gate structure, and a doped semiconductor layer. The source structure is disposed on the substrate. The semiconductor structure is disposed above the source structure. The gate structure is disposed above the source structure and surrounds the semiconductor structure. The doped semiconductor layer is disposed between the source structure and the semiconductor structure.

According to an embodiment of the present invention, a manufacturing method of a semiconductor device is provided. The manufacturing method includes the following steps. A substrate is provided, and a source structure is formed on the substrate. A gate structure is formed above the source structure. A semiconductor structure is formed above the source structure, and the gate structure surrounds the semiconductor structure. A doped semiconductor layer is formed above the source structure before the semiconductor structure is formed, and the doped semiconductor layer is located between the source structure and the semiconductor structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are directed to provide a better understanding of the embodiments and are included as parts of the specification of the present disclosure. These drawings and descriptions are used to illustrate the principles of the embodiments. It should be noted that all drawings are schematic, and the relative dimensions and scales have been adjusted for the convenience of drawing. Identical or similar features in different embodiments are marked with identical symbols.

FIG. 1 is a schematic drawing illustrating a semiconductor device according to a first embodiment of the present invention.

FIG. 2 is a top view schematic drawing illustrating a portion of a semiconductor device according to an embodiment of the present invention.

FIGS. 3-16 are schematic drawings illustrating a manufacturing method of a semiconductor device according to an embodiment of the present invention, wherein FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, FIG. 13 is a schematic drawing in a step subsequent to FIG. 12, FIG. 14 is a schematic drawing in a step subsequent to FIG. 13, FIG. 15 is a schematic drawing in a step subsequent to FIG. 14, and FIG. 16 is a schematic drawing in a step subsequent to FIG. 15.

### DETAILED DESCRIPTION

To provide a better understanding of the presented invention, preferred embodiments will be described in detail. The preferred embodiments of the present invention are illustrated in the accompanying drawings with numbered elements. In addition, the technical features in different embodiments described in the following may be replaced, recombined, or mixed with one another to constitute another embodiment without departing from the spirit of the present invention.

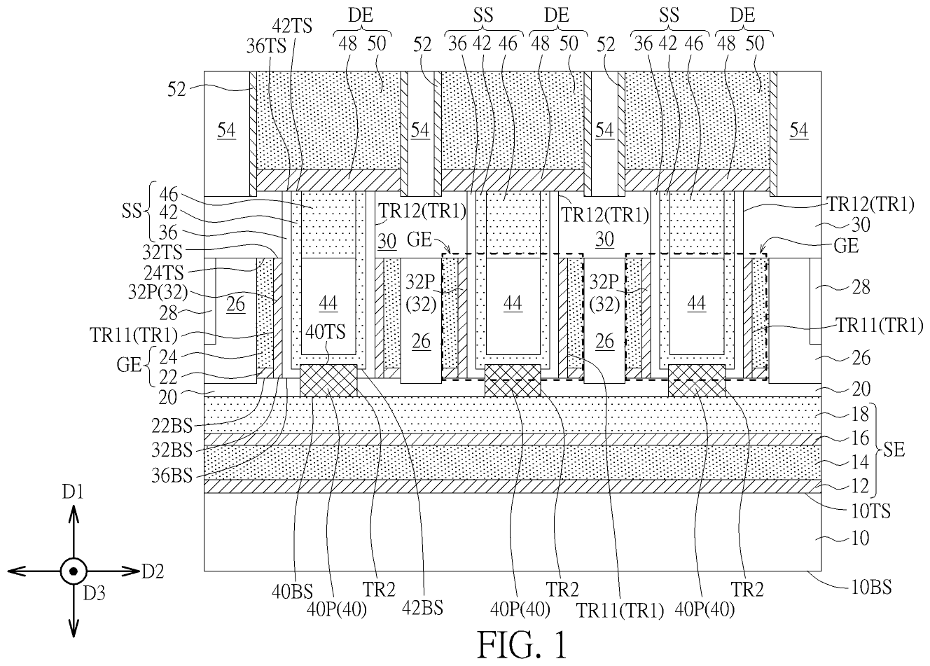

Please refer to FIG. 1. FIG. 1 is a schematic drawing illustrating a semiconductor device 101 according to a first embodiment of the present invention. As shown in FIG. 1, the semiconductor device 101 includes a substrate 10, a source structure SE, a semiconductor structure SS, a gate structure GE, and a doped semiconductor layer 40P. The source structure SE is disposed on the substrate 10. The semiconductor structure SS is disposed above the source structure SE. The gate structure GE is disposed above the source structure SE and surrounds the semiconductor structure SS. The doped semiconductor layer 40P is disposed between the source structure SE and the semiconductor structure SS. The doped semiconductor layer 40P disposed between the source structure SE and the semiconductor structure SS may be used to reduce the connection resistance between the source structure SE and a channel region in the semiconductor structure SS (such as at least a portion of a channel layer 42), and the channel resistance of the semiconductor device 101 may be reduced accordingly for enhancing the operation performance of the semiconductor device.

In some embodiments, the semiconductor structure SS, the gate structure GE, and the doped semiconductor layer 40P may be disposed on the source structure SE in a vertical direction D1. The doped semiconductor layer 40P may be disposed between the source structure SE and the semiconductor structure SS in the vertical direction D1, and the gate structure GE may surround the semiconductor structure SS in a horizontal direction (such as a horizontal direction D2 and/or a horizontal direction D3). The doped semiconductor layer 40P may include a semiconductor material and a dopant located within the semiconductor material. The semiconductor material may include an amorphous silicon semiconductor material or other suitable semiconductor materials, the dopant may include an n-type dopant (such as a phosphorus ion, and/or an arsenic ion, but not limited thereto) or other dopants capable of reducing the electrical resistance, and an electrical resistivity of the doped semiconductor layer 40P is lower than an electrical resistivity of the semiconductor structure SS. In some embodiments, the doped semiconductor layer 40P includes an n-type doped amorphous silicon layer, but not limited thereto. In some embodiments, the source structure SE may include a conductive layer (such as an electrically conductive layer 14) and a semiconductor layer 18, the semiconductor layer 18 may be disposed between the electrically conductive layer 14 and the gate structure GE in the vertical direction D1, and the doped semiconductor layer 40P may be located between the semiconductor layer 18 and the semiconductor structure SS in the vertical direction D1. The semiconductor layer 18 may include silicon-containing semiconductor materials (such as polysilicon semiconductor material or amorphous silicon semiconductor material, but not limited thereto), oxide semiconductor materials (such as indium gallium zinc oxide semiconductor material, but not limited thereto), or other suitable semiconductor materials. In some embodiments, the semiconductor layer 18 may further include dopants (such as dopant ions) located in the semiconductor material, and the electrical resistivity of the semiconductor layer 18 may be relative high for improving the influence between the source structure SE and other parts. Therefore, the electrical resistivity of the doped semiconductor layer 40P may be lower than the resistivity of the semiconductor layer 18, and a dopant ion concentration in the doped semiconductor layer 40P may be higher than a dopant ion concentration in the semiconductor layer 18, but not limited thereto.

In some embodiments, the semiconductor device 101 may further include an insulation structure 44, and the semiconductor structure SS may include a gate dielectric layer 36, a channel layer 42, and a semiconductor layer 46. The insulation structure 44, the gate dielectric layer 36, the channel layer 42, and the semiconductor layer 46 are disposed above the source structure SE. The gate dielectric layer 36 may surround the channel layer 42, the semiconductor layer 46, and the insulation structure 44. The channel layer 42 may be disposed on the gate dielectric layer 36 and surround the semiconductor layer 46 and the insulation structure 44, and the semiconductor layer 46 may be located on the insulation structure 44 in the vertical direction D1. The semiconductor layer 46 and the insulation structure 44 may be located above the doped semiconductor layer 40P in the vertical direction D1, and the insulation structure 44 may be located between the semiconductor layer 46 and the doped semiconductor layer 40P in the vertical direction D1. In some embodiments, a portion of the channel layer 42 may be located between the insulation structure 44 and the doped semiconductor layer 40P in the vertical direction D1, but not limited thereto. The insulation structure 44 may include an oxide insulation material (such as silicon oxide, but not limited thereto) or other suitable insulation materials. The gate dielectric layer 36 may include an oxide dielectric material (such as silicon oxide, but not limited thereto), a high dielectric constant dielectric material (such as a dielectric material with dielectric constant higher than 3.9 or 4.52), or other suitable dielectric materials. The channel layer 42 and the semiconductor layer 46 may include silicon-containing semiconductor materials (such as polysilicon semiconductor material or amorphous silicon semiconductor material, but not limited thereto), oxide semiconductor materials (such as indium gallium zinc oxide semiconductor material, but not limited thereto), or other suitable semiconductor materials. The material composition of the channel layer 42 and the semiconductor layer 46 may be identical to or different from each other. In some embodiments, the channel layer 42 may include dopants (such as dopant ions) located in the semiconductor material described above according to some design considerations and the channel layer 42 needs to have the required semiconductor properties. Therefore, an electrical resistivity of the channel layer 42 may be higher than the electrical resistivity of the doped semiconductor layer 40P, and the dopant ion concentration in the doped semiconductor layer 40P may be higher than a dopant ion concentration in the channel layer 42, but not limited thereto.

In some embodiments, the semiconductor device 101 may further include a dielectric layer 20, a dielectric layer 26, a dielectric layer 28, a dielectric layer 30, a first trench (such as a trench TR1), and a second trench (such as a trench TR2). The dielectric layer 20 may be disposed between the semiconductor layer 18 and the gate structure GE in the vertical direction D1. The dielectric layer 26 may be disposed on the dielectric layer 20 and surround the gate structure GE in the horizontal directions. The dielectric layer 28 may be disposed on the dielectric layer 26 and surround the gate structure GE in the horizontal directions. The dielectric layer 30 may cover the gate structure GE, the dielectric layer 28 and the dielectric layer 26 in the vertical direction D1. The trench TR2 may penetrate through the dielectric layer 20 in the vertical direction D1, and the trench TR1 may penetrate through the dielectric layer 30 and the gate structure GE in the vertical direction D1. For example, the trench TR1 may include a first portion TR11 and a second portion TR12 located on the first portion TR11. The first portion TR11 may be located in the gate structure GE, the second portion TR12 may be located in the dielectric layer 30, and a width of the first portion TR11 may be greater than a width of the second portion TR12, but not limited thereto. In addition, the insulation structure 44 and the semiconductor structure SS may be located in the trench TR1, and at least a portion of the doped semiconductor layer 40P may be located in the trench TR2. In some embodiments, the doped semiconductor layer 40P may be partly located in the trench TR2 and partly located in the trench TR1, a lower surface 40BS of the doped semiconductor layer 40P may directly contact the semiconductor layer 18, and the doped semiconductor layer 40P located in the trench TR1 may directly contact the gate dielectric layer 36 and the channel layer 42. In addition, an upper surface 40TS of the doped semiconductor layer 40P may be higher than a lower surfaced 22BS of the gate structure GE, a lower surface 36BS of the gate dielectric layer 36, and/or a lower surface 42BS of the channel layer 42 in the vertical direction D1. Therefore, the gate structure GE and the gate dielectric layer 36 may surround the doped semiconductor layer 40P in the horizontal directions (such as the horizontal direction D2 and/or the horizontal direction D3), and the channel layer 42 may also surround the doped semiconductor layer 40P in the horizontal directions (such as the horizontal direction D2 and/or the horizontal direction D3), but not limited thereto. In some embodiments, the upper surface 40TS may be the topmost surface of the doped semiconductor layer 40P in the vertical direction D1, the lower surface 36BS may be the bottommost surface of the gate dielectric layer 36 in the vertical direction D1, and the lower surface 42BS may be the bottommost surface of the channel layer 42 in the vertical direction D1.

In some embodiments, the semiconductor device 101 may further include a barrier pattern 32P disposed above the source structure SE. The barrier pattern 32P may surround the semiconductor structure SS in the horizontal directions, and at least a part of the barrier pattern 32P may be located between the gate structure GE and the semiconductor structure SS. The barrier pattern 32P may include titanium nitride, tantalum nitride, or other suitable electrically conductive barrier materials. In some embodiments, the barrier pattern 32P may be disposed in the first portion TR11 of the trench TR1, and a part of the dielectric layer 30 may cover an upper surface 32TS of the barrier pattern 32P in the vertical direction D1, but not limited thereto. In addition, an upper surface 36TS of the gate dielectric layer 36 and an upper surface 42TS of the channel layer 42 may be higher than the upper surface 32TS of the barrier pattern 32P and an upper surface 24TS of the gate structure GE in the vertical direction D1, and the lower surface 22BS of the gate structure GE, a lower surface 32BS of the barrier pattern 32P, and the lower surface 36BS of the gate dielectric layer 36 may be connected with the dielectric layer 20 respectively and may be substantially coplanar, but not limited thereto. In some embodiments, the semiconductor device 101 may further include a drain structure DE, a sidewall structure 52, and a dielectric layer 54. The dielectric layer 54 may be disposed on the dielectric layer 30, the drain structure DE may be disposed on the semiconductor structure SS, and the sidewall structure 52 may be disposed on a sidewall of the drain structure DE. The dielectric layer 20, the dielectric layer 26, the dielectric layer 28, the dielectric layer 30, and the dielectric layer 54 may include an oxide dielectric material (such as silicon oxide, but not limited thereto), a nitride dielectric material (such as silicon nitride, but not limited thereto), tetraethoxysilane (TEOS), or other suitable dielectric materials. The sidewall structure 52 may include a nitride dielectric material (such as silicon nitride, but not limited thereto) or other suitable dielectric materials.

In some embodiments, the semiconductor device 101 may include a plurality of the gate structures GE and the components located corresponding to the gate structures GE, such as the barrier patterns 32P, the doped semiconductor layers 40P, the semiconductor structures SS, the insulation structures 44, and the drain structures DE, and the source structure SE may be connected with the semiconductor structures SS, but not limited thereto. In some embodiments, the source structure SE, the gate structure GE, and the drain structure DE may respectively include layers of electrically conductive materials. For example, the source structure SE may further include a barrier layer 12 located between the substrate 10 and the electrically conductive layer 14 in the vertical direction D1 and a barrier layer 16 located between the electrically conductive layer 14 and the semiconductor layer 18 in the vertical direction D1; the gate structure GE may include a barrier layer 22 and an electrically conductive layer 24 disposed on the barrier layer 22 in the vertical direction D1; and the drain structure DE may include a barrier layer 48 and an electrically conductive layer 50 disposed on the barrier layer 48 in the vertical direction D1, but not limited thereto. The barrier layer 12, the barrier layer 16, the barrier layer 22, and the barrier layer 48 described above may include titanium nitride, tantalum nitride, or other suitable electrically conductive barrier materials, and the material compositions of the barrier layer 12, the barrier layer 16, the barrier layer 22, the barrier layer 48, and the barrier pattern 32P may be identical to or different from one another. The electrically conductive layer 14, the electrically conductive layer 24, and the electrically conductive layer 50 may include copper, aluminum, tungsten, or other electrically conductive materials with low electrical resistivity, and the material compositions of the electrically conductive layer 14, the electrically conductive layer 24, and the electrically conductive layer 50 may be identical to or different from one another. In addition, the barrier pattern 32P may be disposed between the electrically conductive layer 24 and the semiconductor structure SS for providing barrier effect between the electrically conductive layer 24 and the semiconductor structure SS, and the barrier pattern 32P may directly contact the electrically conductive layer 24, the barrier layer 22, and the gate dielectric layer 36, but not limited thereto.

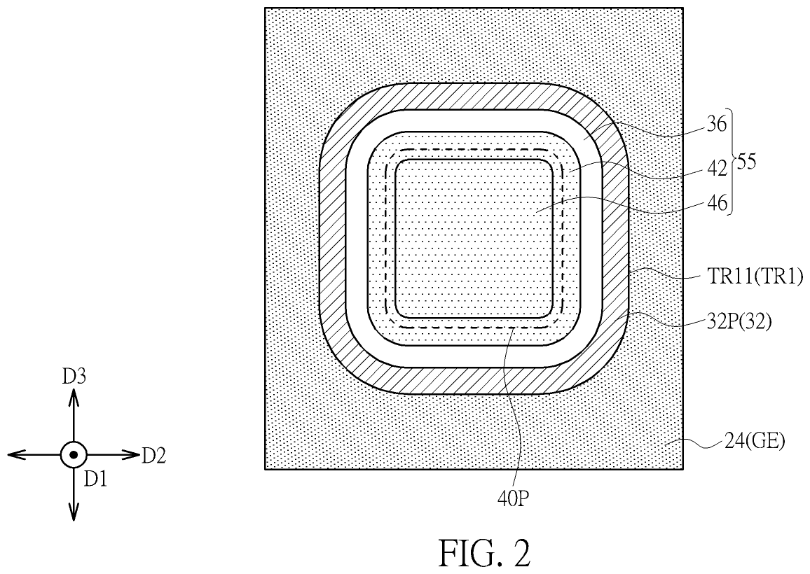

Please refer to FIG. 1 and FIG. 2. FIG. 2 is a top view schematic drawing illustrating a portion of a semiconductor device according to an embodiment of the present invention. In some embodiments, FIG. 2 may be regarded as a top view schematic drawing illustrating a portion of the semiconductor device 101 described above, but not limited thereto. As shown in FIG. 1 and FIG. 2, in some embodiments, the barrier pattern 32P, the gate dielectric layer 36, and the channel layer 42 may be cylindrical structures extending in the vertical direction D1, respectively, the insulation structure 44 may be a columnar structure extending in the vertical direction D1, and central axes of the cylindrical structures and the columnar structure extending in the vertical direction D1 may substantially overlap one another when viewed in the vertical direction D1, but not limited thereto. In the top view diagram of the semiconductor device 101, the gate structure GE may surround the barrier pattern 32P, the semiconductor structure SS, the insulation structure 44, and the doped semiconductor layer 40P located in the trench TR1 in the horizontal directions (such as the horizontal direction D2, the horizontal direction D3, and/or other horizontal directions substantially orthogonal to the vertical direction D1), and the barrier pattern 32P may surround the semiconductor structure SS and the insulation structure 44 in the horizontal directions. The semiconductor structure SS may surround the insulation structure 44 in the top view diagram and the cross-sectional diagram of the semiconductor device 101. It is worth noting that the shape of the trench (such as the first portion TR11 of the trench TR1) in the top view diagram of the semiconductor device according to the present invention is not limited to the condition illustrated in FIG. 2 and the trench with other shapes may be applied also according to some design considerations.

In some embodiments, the substrate 10 may include a base layer (not illustrated) and a dielectric layer disposed on the base layer. The base layer may include a semiconductor substrate such as a silicon substrate, a silicon germanium semiconductor substrate, a silicon-on-insulator (SOI) substrate, or a substrate made of other suitable materials. In addition, other devices (such as transistors) and/or circuits (not illustrated) may be formed on the base layer described above, and the semiconductor device 101 may be electrically connected downward and/or upward to other devices and/or circuits on the base layer. In some embodiments, the manufacturing method of the semiconductor device 101 may be integrated with the back end of line (BEOL) process in the semiconductor manufacturing process, and the semiconductor device 101 may be regarded as a vertical transistor structure including a gate surrounding a semiconductor layer in the horizontal directions, but not limited thereto.

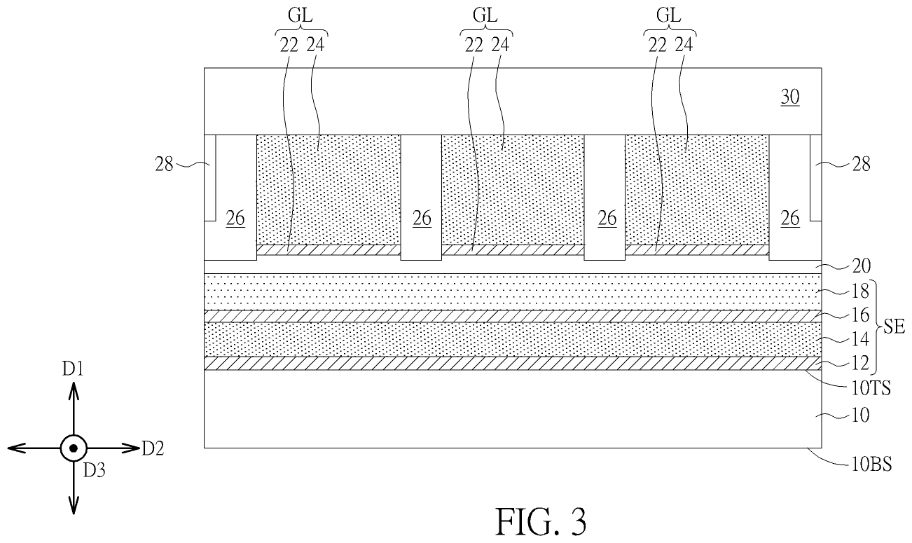

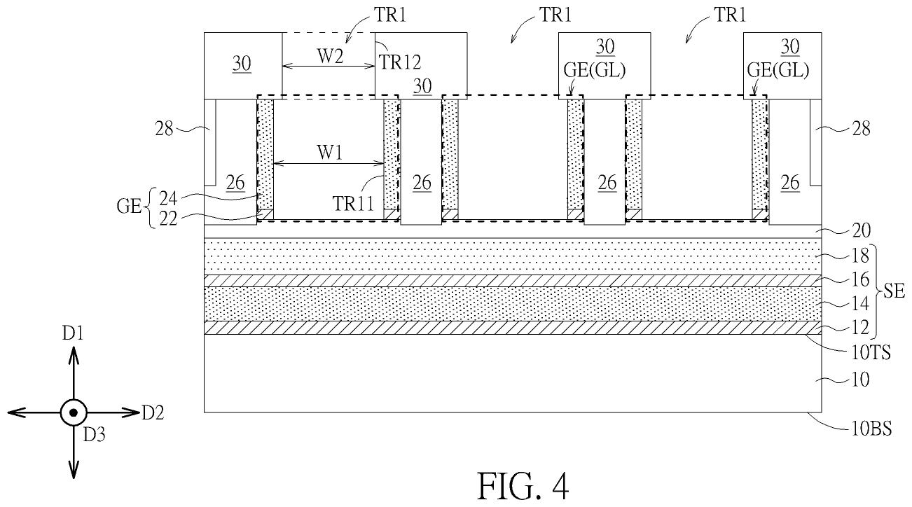

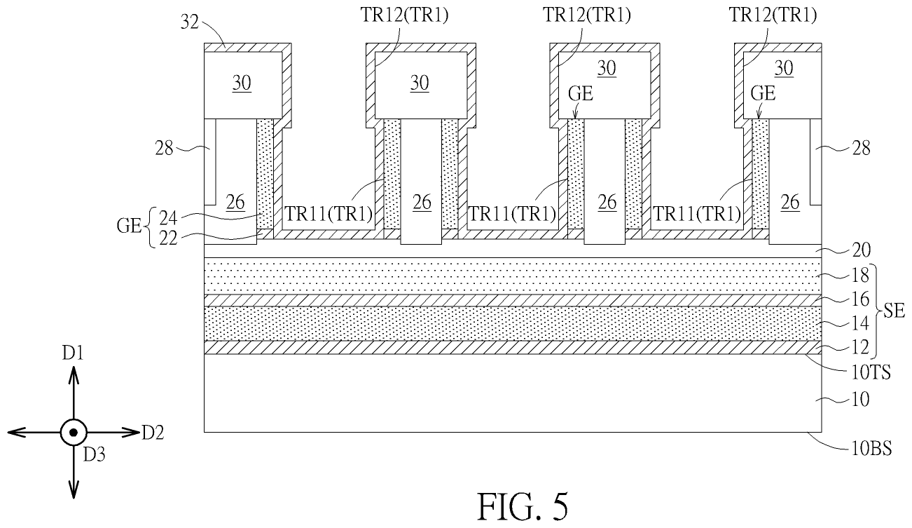

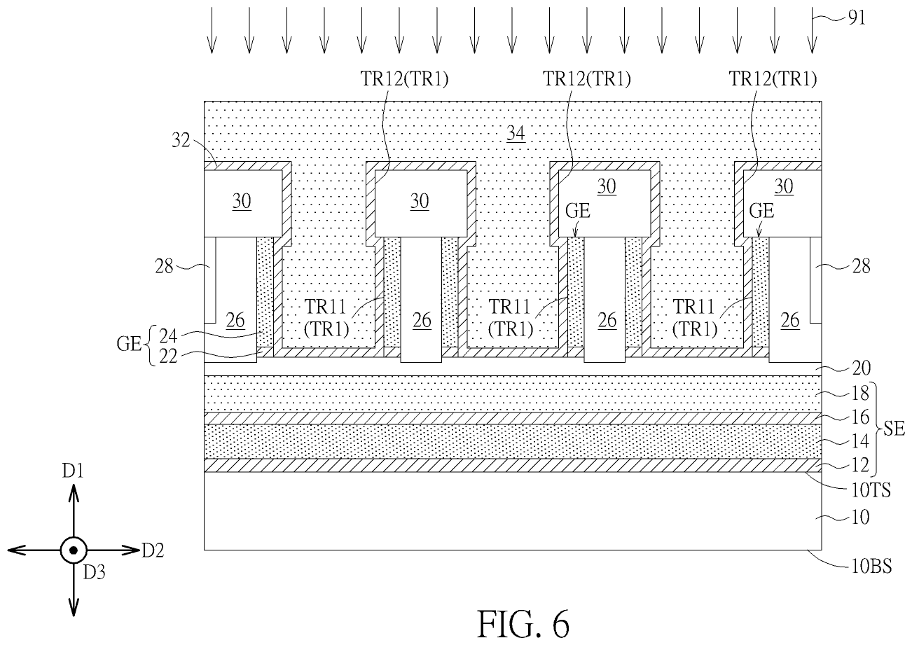

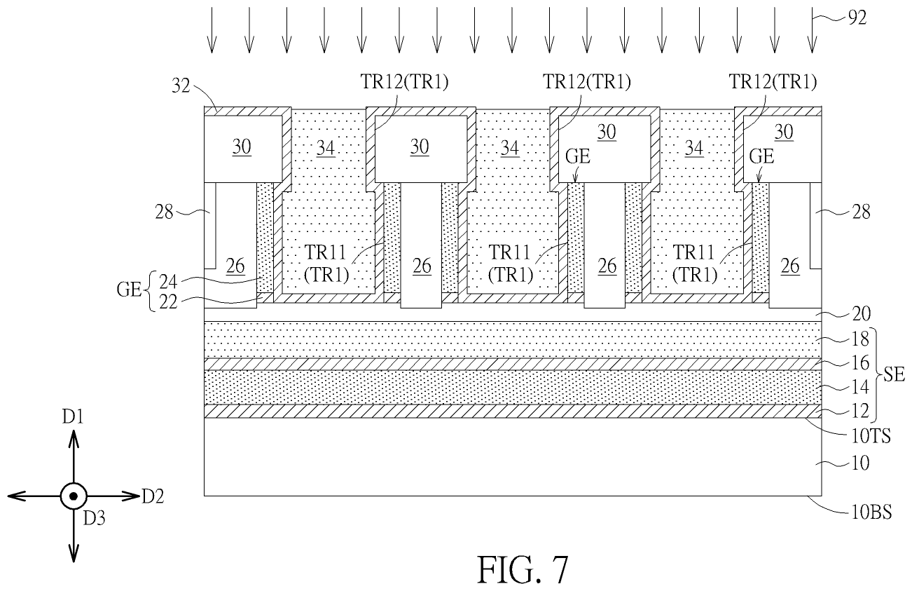

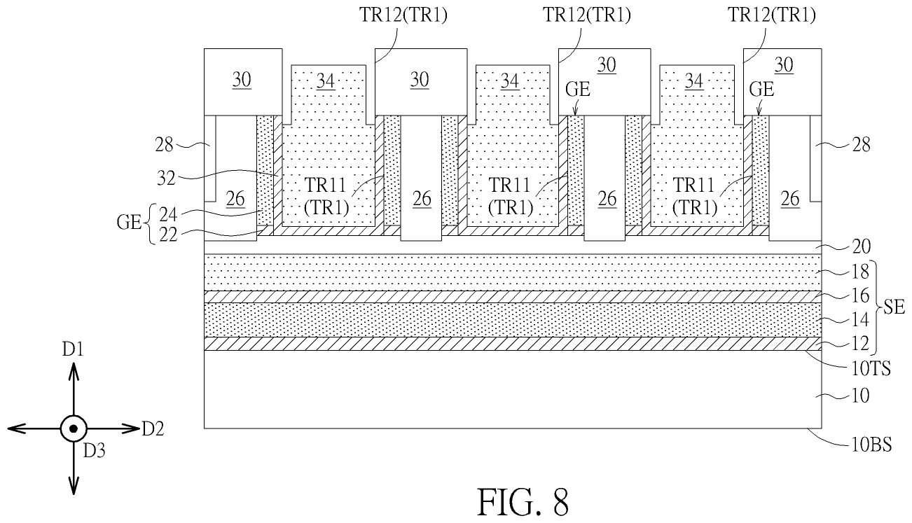

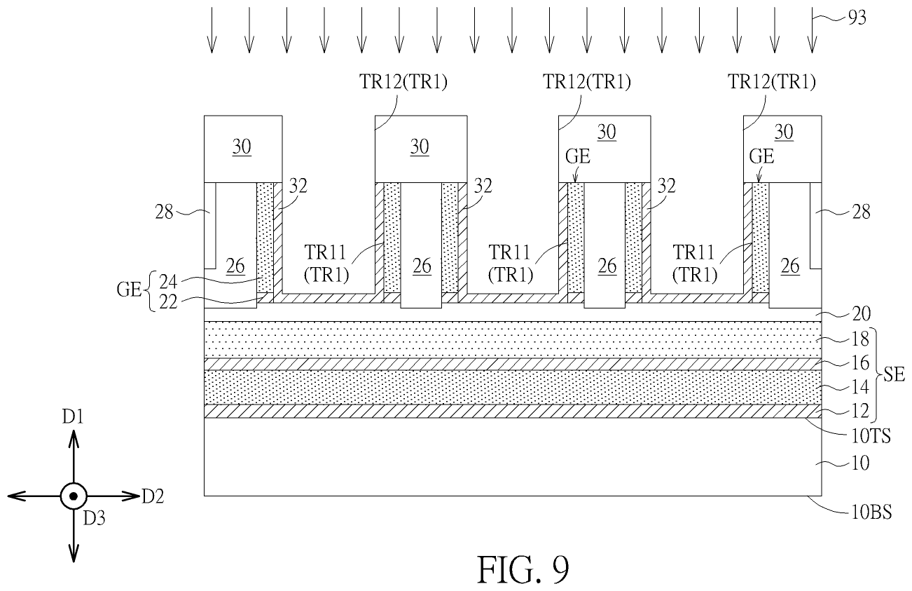

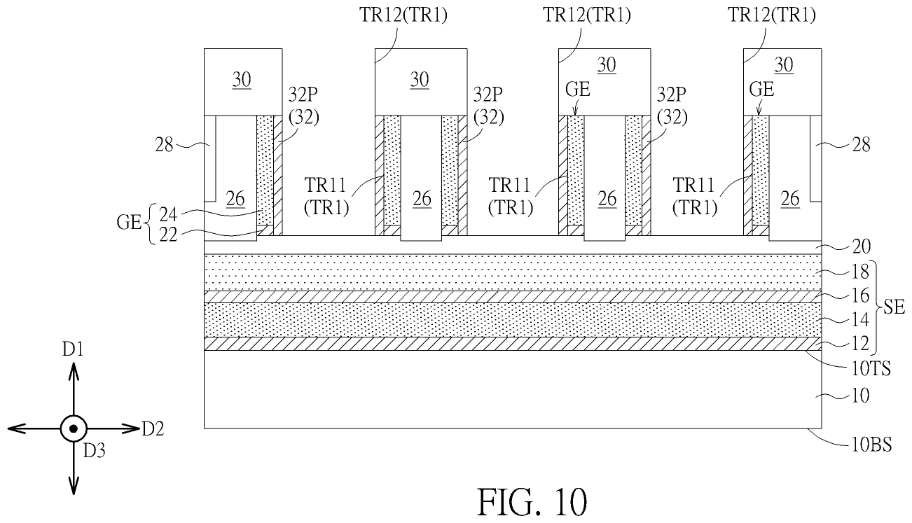

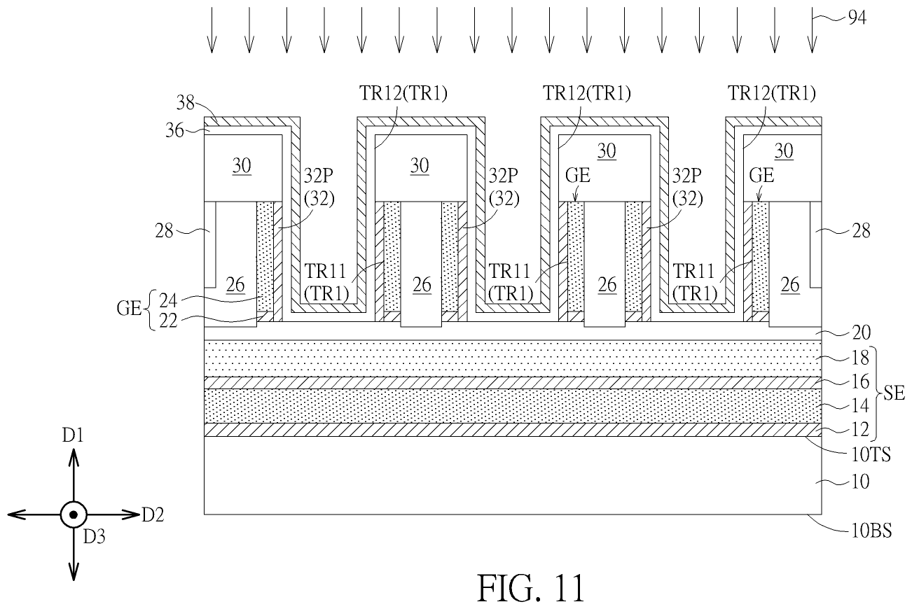

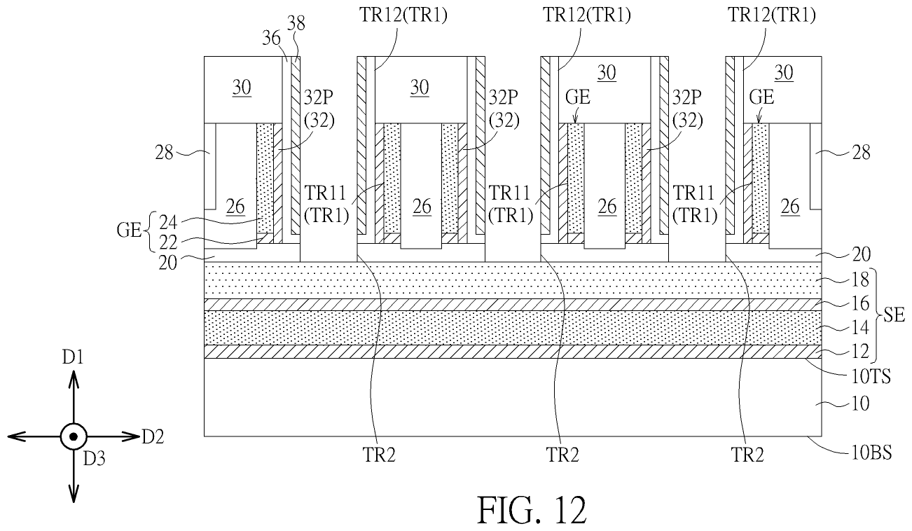

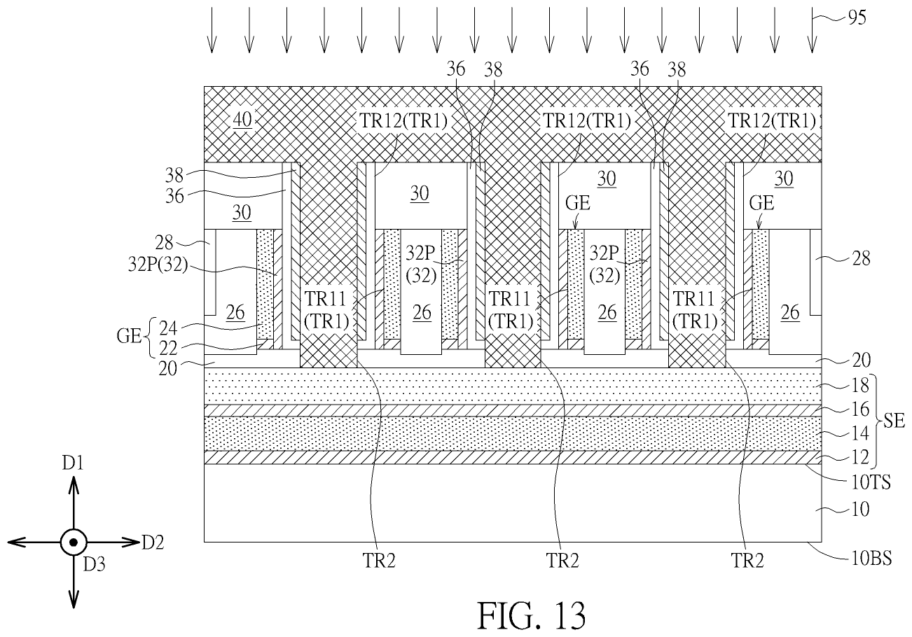

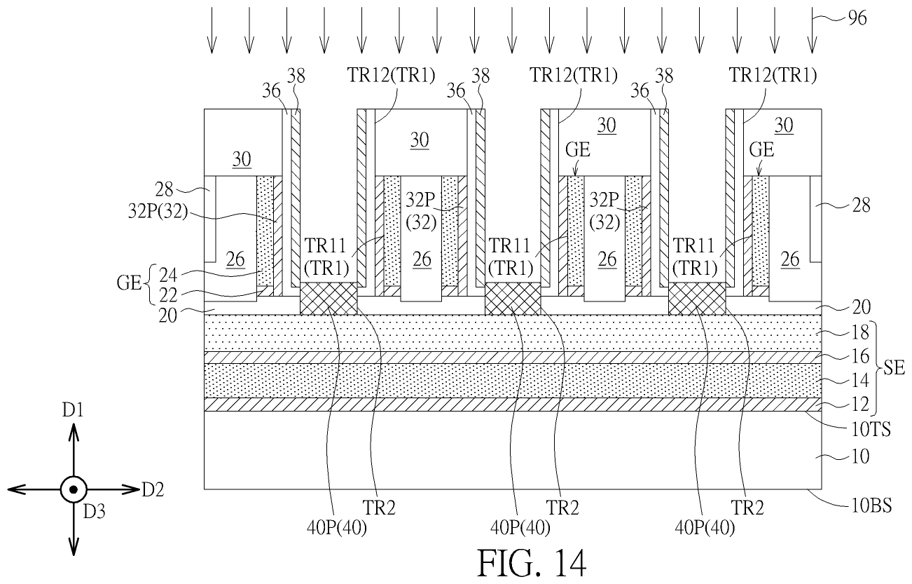

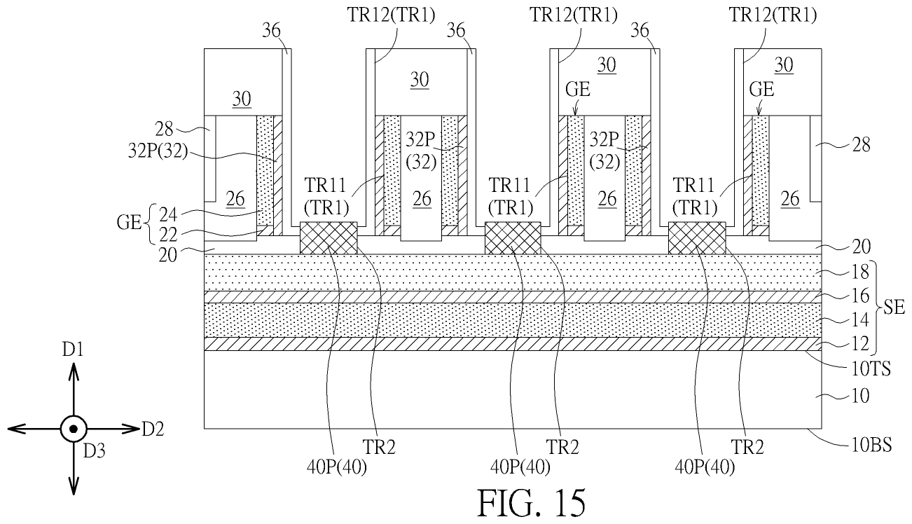

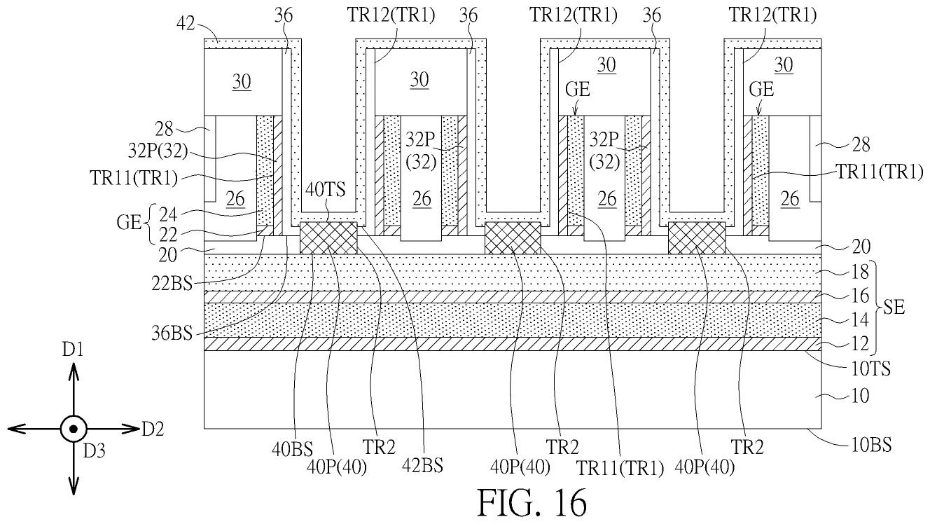

Please refer to FIG. 1, FIG. 2, and FIGS. 3-16. FIGS. 3-16 are schematic drawings illustrating a manufacturing method of a semiconductor device according to an embodiment of the present invention, wherein FIG. 4 is a schematic drawing in a step subsequent to FIG. 3, FIG. 5 is a schematic drawing in a step subsequent to FIG. 4, FIG. 6 is a schematic drawing in a step subsequent to FIG. 5, FIG. 7 is a schematic drawing in a step subsequent to FIG. 6, FIG. 8 is a schematic drawing in a step subsequent to FIG. 7, FIG. 9 is a schematic drawing in a step subsequent to FIG. 8, FIG. 10 is a schematic drawing in a step subsequent to FIG. 9, FIG. 11 is a schematic drawing in a step subsequent to FIG. 10, FIG. 12 is a schematic drawing in a step subsequent to FIG. 11, FIG. 13 is a schematic drawing in a step subsequent to FIG. 12, FIG. 14 is a schematic drawing in a step subsequent to FIG. 13, FIG. 15 is a schematic drawing in a step subsequent to FIG. 14, and FIG. 16 is a schematic drawing in a step subsequent to FIG. 15. In some embodiments, FIG. 1 may be regarded as a schematic drawing in a step subsequent to FIG. 16, but not limited thereto. As shown in FIG. 1, the manufacturing method of the semiconductor device in this embodiment may include the following steps. The substrate 10 is provided, and the source structure SE is formed above the substrate 10. The gate structure GE is formed above the source structure SE. The semiconductor structure SS is formed above the source structure SE, and the gate structure GE surrounds the semiconductor structure SS. The doped semiconductor layer 40P is formed above the source structure SE before the semiconductor structure SS is formed, and the doped semiconductor layer 40P is located between the source structure SE and the semiconductor structure SS.

Specifically, the manufacturing method of the semiconductor device in this embodiment may include but is not limited to the following steps. As shown in FIG. 3, the source structure SE, the dielectric layer 20, a gate layer GL, the dielectric layer 26, the dielectric layer 28, and the dielectric layer 30 may be formed sequentially on an upper surface 10TS of the substrate 10. The upper surface 10TS and a lower surface 10BS may be two opposite surfaces of the substrate 10 in the vertical direction D1. The gate layer GL may include the barrier layer 22 and the electrically conductive layer 24 formed on the barrier layer 22. Subsequently, as shown in FIG. 4, the first trench (such as the trench TR1) may be formed, and the trench TR1 may penetrate through the dielectric layer 30 and the gate layer GL in the vertical direction D1 for forming the gate structure GE. The trench TR1 may be formed by removing a part of the dielectric layer 30 and a part of the gate layer GL, and the gate structure GE may be composed of the gate layer GL remaining after the trench TR1 is formed. Therefore, the dielectric layer 20, the gate layer GL, and the dielectric layer 30 may be regarded as being formed above the source structure SE before the gate structure GE is formed, and at least a part of the dielectric layer 20 is located between the gate structure GE and the source structure SE in the vertical direction D1. In some embodiments, the trench TR1 may include the first portion TR11 and the second portion TR 12, the first portion TR11 is located in the gate structure GE, and the second portion TR 12 is located in the dielectric layer 30. A width W1 of the first portion TR11 is greater than a width W2 of the second portion TR12 for coordinating with related processes of forming the barrier pattern 32P subsequently. In some embodiments, the width W1 and the width W2 may be regarded as the length of the first portion TR11 and the length of the second portion TR12 in the horizontal direction (such as the horizontal direction D2), but not limited thereto. Additionally, the method of removing a part of the dielectric layer 30 and a part of the gate layer GL for forming the trench TR1 may include an etching process or other suitable removing approaches. In some embodiments, a part of the dielectric layer 30 and a part of the gate layer GL may be removed by a photolithography process for exposing the dielectric layer 20 first, and the gate layer GL may then be etched laterally by a wet etching process or a cleaning process with higher etching selectivity between the dielectric layer 30 and the gate layer GL for forming the trench TR1 including the first portion TR11 that is relatively wide and the second portion TR 12 that is relatively narrow.

As shown in FIG. 5, a barrier layer 32 may be formed, and the barrier layer 32 may be partly formed in the trench TR1 and partly formed outside the trench TR1, such as being formed conformally on the sidewall of the bottom of the trench TR1 and conformally on the dielectric layer 30. Therefore, the barrier layer 32 may be partly formed in the first portion TR11 of the trench TR1 and partly formed in the second portion TR12 of the trench TR1. As shown in FIG. 6, after the barrier layer 32 is formed, a mask material 34 may be formed. The mask material 34 may cover the barrier layer 32, the mask material 34 may be partly formed in the trench TR1 and partly formed outside the trench TR1, and the trench TR1 may be fully filled with the barrier layer 32 and the mask material 34. The mask material 34 may include spin-on-carbon (SOC) or other suitable mask materials. Subsequently, as shown in FIG. 6 and FIG. 7, a removing process 91 may be performed to the mask material 34 for removing the mask material 34 located outsider the trench TR1 and exposing the barrier layer 32 located on the dielectric layer 30 in the vertical direction D1. In some embodiments, the removing process 91 may include an etching process (such as an etching back process performed to the mask material 34) or other suitable removing approaches. After the removing process 91, the mask material 34 formed in the trench TR1 may cover the barrier layer 32 located in the trench TR1. As shown in FIG. 7 an FIG. 8, a first removing process (such as a removing process 92) may then be performed for removing the barrier layer 32 located in the second portion TR12 of the trench TR and the barrier layer 32 located on the dielectric layer 30 in the vertical direction D1, and a part of the barrier layer 32 may remain in the first portion TR11 of the trench TR1 after the removing process 92. In some embodiments, the removing process may include an etching process (such as an etching process where an etching rate to the mask material 34 is lower than an etching rate to the barrier layer 32) or other suitable removing approaches, and a part of the mask material 34 may be removed by the removing process 92, but not limited thereto.

As shown in FIG. 8 and FIG. 9, after the removing process 92, the mask material 34 may be removed. As shown in FIGS. 8-10, after the mask material 34 is removed, a second removing process (such as a removing process 93) may be performed for removing the barrier layer 32 located at the bottom of the first portion TR11 of the trench TR1 and exposing the dielectric layer 20, and the barrier layer 32 remaining in the trench TR1 after the removing process 93 becomes the barrier pattern 32P. In some embodiments, the removing process 93 may include an etching process (such as an anisotropic dry etching process) or other suitable removing approaches for avoiding and/or reducing lateral etching to the barrier layer 32. By the manufacturing method described above, the barrier pattern 32P may be formed in a self-aligned configuration, but not limited thereto. It is worth noting that the method of forming the barrier pattern 32P may include but is not limited to the steps illustrated in FIGS. 4-10 described above, and the barrier pattern 32P may be formed in the trench TR1 by other suitable manufacturing methods according to some design considerations.

As shown in FIG. 11, after the barrier pattern 32P is formed, the gate dielectric layer 36 may be formed, and a sacrificial layer 38 may be formed on the gate dielectric layer 36. The gate dielectric layer 36 may be formed conformally on the bottom of the trench TR1, the sidewall of the barrier pattern 32P, and the surface of the dielectric layer 30, and the sacrificial layer 38 may be formed conformally on the gate dielectric layer 36. The sacrificial layer 38 may include polysilicon or other sacrificial materials different from the material of the gate dielectric layer 36. As shown in FIG. 11 and FIG. 12, a removing process 94 may then be performed for removing a part of the sacrificial layer 38, a part of the gate dielectric layer 36, and a part of the dielectric layer 20, so as to form the second trench (such as the trench TR2), and the sacrificial layer 38 and the gate dielectric layer 36 may remain on the sidewall of the trench TR1 after the removing process 94. Therefore, the trench TR2 is formed after the trench TR1 is formed, and the trench TR2 penetrates through the dielectric layer 20 in the vertical direction D1. As shown in FIG. 13, after the trench TR2 is formed, a doped semiconductor material 40 may be formed. The doped semiconductor material 40 may be partly formed in the trench TR2 and the trench TR1 and partly formed outside the trench TR2 and the trench TR1. The trench TR2 may be fully filled with the doped semiconductor material 40, and the trench TR1 may be fully filled with the sacrificial layer 38, the gate dielectric layer 36, and the doped semiconductor material 40, but not limited thereto. Subsequently, as shown in FIG. 13 and FIG. 14, a removing process 95 may be performed to the doped semiconductor material 40 for removing the doped semiconductor material 40 located outside the trench TR2 and the trench TR1 and at least a part of the doped semiconductor material 40 located in the trench TR1 for forming the doped semiconductor layer 40P. In some embodiments, the removing process 95 may include an etching process (such as an etching back process performed to the doped semiconductor material 40) or other suitable removing approaches, and the doped semiconductor material 40 remaining after the removing process 95 becomes the doped semiconductor layer 40P. In some embodiments, the process conditions of the removing process 95 may be controlled for keeping the doped semiconductor material 40 located in the trench TR1 without being completely removed by the removing process 95. The doped semiconductor layer 40P may be partly formed in the trench TR2 and partly formed in the trench TR1, and the upper surface of the doped semiconductor layer 40P may be higher than a lower surface of the sacrificial layer 38 in the vertical direction D1.

As shown in FIG. 14 and FIG. 15, after the doped semiconductor layer 40P is formed, a removing process 96 may be performed for removing at least a part of the sacrificial layer 38. In some embodiments, the removing process 96 may include an etching process (such as a wet etching process with relatively high etching selectivity) or other suitable removing approaches for avoiding and/or reducing etching damages to material layers except the sacrificial layer 38. In some embodiments, a part of the sacrificial layer 38 may remain (not illustrated) after the removing process 96, but not limited thereto. Subsequently, as shown in FIG. 16, the channel layer 42 may be formed, and the channel layer 42 may be partly formed in the trench TR1 and partly formed outside the trench TR1. In some embodiments, the channel layer 42 may directly contact the doped semiconductor layer 40P, the upper surface 40TS of the doped semiconductor layer 40P may be higher than the lower surface 22BS of the gate structure GE, the lower surface 36BS of the gate dielectric layer 36, and the lower surface 42BS of the channel layer 42 in the vertical direction D1 for increasing the contact area between the doped semiconductor layer 40P and the channel layer 42, but not limited thereto. As shown in FIG. 16 and FIG. 1, the insulation structure 44 and the semiconductor layer 46 may be formed in the trench TR1 for forming the semiconductor structure SS in the trench TR1. In some embodiments, the channel layer 42 and the semiconductor layer 46 may be partly formed in the trench TR1 and partly formed outside the trench TR1, and a planarization process may be carried out for removing the material layers located outside the trench TR1 for forming the channel layer 42 and the semiconductor layer 46 illustrated in FIG. 1. Therefore, the upper surface of the dielectric layer 30, the upper surface 36TS of the gate dielectric layer 36, the upper surface 42TS of the channel layer 42, and the upper surface of the semiconductor layer 46 may be substantially coplanar, but not limited thereto. In addition, the barrier pattern 32P may surround the semiconductor structure SS in the horizontal directions, a portion of the barrier pattern 32P may be located between the gate structure GE and the semiconductor structure SS in the horizontal directions, and another portion of the barrier pattern 32P may be located between the gate structure GE and the doped semiconductor layer 40P in the horizontal directions. In this embodiment, the gate dielectric layer 36 may be formed in the trench TR1 before the step of forming the doped semiconductor layer 40P, and the channel layer 42, the insulation structure 44, and the semiconductor layer 46 may be formed in the trench TR1 after the step of forming the doped semiconductor layer 40P. It is worth noting that, the method of forming the semiconductor structure SS in this embodiment may include but is not limited to the steps illustrated in FIGS. 11-16 and FIG. 1 described above, and the semiconductor structure SS may also be formed in the trench TR1 by other suitable manufacturing methods according to some design considerations. Subsequently, as shown in FIG. 1, the drain structure DE, the sidewall structure 52, and the dielectric layer 54 described above may be formed for forming the semiconductor device 101.

To summarize the above descriptions, in the semiconductor device and the manufacturing method thereof according to the present invention, the doped semiconductor layer may be disposed between the source structure and the semiconductor structure for reducing the connection resistance between the source structure and the channel region in the semiconductor structure, and the channel resistance of the semiconductor device may be reduced accordingly for enhancing the operation performance of the semiconductor device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor device, comprising:
a substrate;
a source structure disposed on the substrate;
a semiconductor structure disposed above the source structure;
a gate structure disposed above the source structure and surrounding the semiconductor structure; and
a doped semiconductor layer disposed between the source structure and the semiconductor structure.

2. The semiconductor device according to claim 1, wherein an electrical resistivity of the doped semiconductor layer is lower than an electrical resistivity of the semiconductor structure.

3. The semiconductor device according to claim 1, wherein the source structure comprises:
a conductive layer; and
a semiconductor layer disposed between the conductive layer and the gate structure, wherein the doped semiconductor layer is located between the semiconductor layer and the semiconductor structure.

4. The semiconductor device according to claim 3, wherein an electrical resistivity of the doped semiconductor layer is lower than an electrical resistivity of the semiconductor layer.

5. The semiconductor device according to claim 3, wherein a dopant ion concentration in the doped semiconductor layer is higher than a dopant ion concentration in the semiconductor layer.

6. The semiconductor device according to claim 1, wherein the semiconductor structure comprises:
a gate dielectric layer disposed above the source structure, wherein the gate dielectric layer surrounds the doped semiconductor layer; and
a channel layer disposed on the gate dielectric layer, wherein the channel layer surrounds the doped semiconductor layer.

7. The semiconductor device according to claim 6, wherein a dopant ion concentration in the doped semiconductor layer is higher than a dopant ion concentration in the channel layer.

8. The semiconductor device according to claim 6, wherein a topmost surface of the doped semiconductor layer is higher than a bottommost surface of the gate dielectric layer and a bottommost surface of the channel layer.

9. The semiconductor device according to claim 1, further comprising:
a barrier pattern disposed above the source structure, wherein the barrier pattern surrounds the semiconductor structure, and at least a part of the barrier pattern is located between the gate structure and the semiconductor structure.

10. The semiconductor device according to claim 1, wherein an upper surface of the doped semiconductor layer is higher than a lower surface of the gate structure.

11. The semiconductor device according to claim 1, wherein the doped semiconductor layer comprises an n-type doped amorphous silicon layer.

12. A manufacturing method of a semiconductor device, comprising:
providing a substrate;
forming a source structure on the substrate;
forming a gate structure above the source structure,
forming a semiconductor structure above the source structure, wherein the gate structure surrounds the semiconductor structure; and
forming a doped semiconductor layer above the source structure before the semiconductor structure is formed, wherein the doped semiconductor layer is located between the source structure and the semiconductor structure.

13. The manufacturing method of the semiconductor device according to claim 12, further comprising:
forming a gate layer and a first dielectric layer above the source structure before the gate structure is formed; and
forming a first trench, wherein the first trench penetrates through the first dielectric layer and the gate layer for forming the gate structure, and the semiconductor structure is formed in the first trench.

14. The manufacturing method of the semiconductor device according to claim 13, wherein the first trench comprises:
a first portion located in the gate structure; and
a second portion located in the first dielectric layer, wherein a width of the first portion is greater than a width of the second portion.

15. The manufacturing method of the semiconductor device according to claim 14, further comprising:
forming a barrier pattern in the first trench, wherein the barrier pattern surrounds the semiconductor structure, a portion of the barrier pattern is located between the gate structure and the semiconductor structure, and another portion of the barrier pattern is located between the gate structure and the doped semiconductor layer.

16. The manufacturing method of the semiconductor device according to claim 15, wherein a method of forming the barrier pattern comprises:
forming a barrier layer in the first trench, wherein the barrier layer is partly formed in the first portion of the first trench and partly formed in the second portion of the first trench;
forming a mask material in the first trench after the barrier layer is formed, wherein the mask material covers the barrier layer located in the first trench;
performing a first removing process for removing the barrier layer located in the second portion of the first trench;
removing the mask material after the first removing process; and
performing a second removing process after the mask material is removed for removing the barrier layer located at a bottom of the first portion of the first trench, wherein the barrier layer remaining in the first trench after the second removing process becomes the barrier pattern.

17. The manufacturing method of the semiconductor device according to claim 13, further comprising:
forming a second dielectric layer above the source structure before the gate structure is formed, wherein at least a portion of the second dielectric layer is located between the gate structure and the source structure; and
forming a second trench after the first trench is formed, wherein the second trench penetrates through the second dielectric layer, and at least a portion of the doped semiconductor layer is formed in the second trench.

18. The manufacturing method of the semiconductor device according to claim 13, wherein a method of forming the semiconductor structure comprises:
forming a gate dielectric layer in the first trench before the doped semiconductor layer is formed, wherein the gate dielectric layer surrounds the doped semiconductor layer.

19. The manufacturing method of the semiconductor device according to claim 12, wherein an upper surface of the doped semiconductor layer is higher than a lower surface of the gate structure.

20. The manufacturing method of the semiconductor device according to claim 12, wherein the source structure comprises:
a conductive layer; and
a semiconductor layer disposed between the conductive layer and the gate structure, wherein the doped semiconductor layer is located between the semiconductor layer and the semiconductor structure.
